(19) United States
(12) Patent Application Publication
(10) Pub. No.: US 2026/0369769 A1
(43) Pub. Date: Nov. 19, 2026

(54) SYSTEM AND METHOD FOR ELECTROMAGNETIC SHIELDING OF ELECTRONIC MODULES IN ELECTRIC VEHICLES

(71) Applicant: GM GLOBAL TECHNOLOGY OPERATIONS LLC, Detroit, MI (US)

(72) Inventors: Yi Liu, Troy, MI (US); Mary Victoria Reiber, Royal Oak, MI (US); Bhavesh Shah, Troy, MI (US)

(73) Assignee: GM GLOBAL TECHNOLOGY OPERATIONS LLC, Detroit, MI (US)

(21) Appl. No.: 19/208,878

(22) Filed: May 15, 2025

(51) Int. Cl. H01M 50/24; B60L 50/60; B60R 13/08; D03D 15/67; H01M 50/249; H05K 9/00

(52) U.S. Cl. CPC H01M 50/24; B60L 50/60; B60R 13/08; D03D 15/67; H01M 50/249; H05K 9/009; D10B 2505/02; D10B 2505/12; H01M 2220/20

(57) ABSTRACT

Method and systems of shielding an electric component include designing a shield to enclose, at least partly, the electric component. A shielding density of the shield is determined. Strands are produced from a combination of nonmetallic fibers and metallic wire. Fabric is woven from the strands with the metallic wire extending in at least two directions. The shield is formed from layers of the fabric combined with a resin.

The technical field generally relates to electromagnetic shielding, and more particularly relates to shielding for electronic modules in applications such as electric vehicles.

In any number of applications involving electronic circuitry, electromagnetic (EM) interference, radio frequency (RF) interference and electrostatic (ES) discharge are preferably avoided. EM and RF signals may emanate from any electrical device and from nature. ES discharge may result from components being at different electric potentials. Interference occurs when an EM/RF/ES transmission travels in the direction of an electronic device with the ability to disrupt operation. To avoid interference, shielding devices and grounding approaches have been developed to protect electronics from EM and RF interference and from ES discharge sources to avoid performance degradation or disruption. EM shielding techniques address interference from electromagnetic sources, RF shielding techniques address interference from radio frequency sources and ES grounding techniques address potential buildup. Shielding may be implemented to avoid both inputs and outputs of RF interference, ES interference, and EM interference so that electronic functions are not adversely impacted.

In automotive applications, various modules such as electronic control units, power electronic modules, sensor modules, battery pack modules, buses/cables, infotainment systems, navigation systems, communication systems, and other vehicle electronics may be shielded to maintain the performance of these components, ensuring accurate operation. In applications such as electric vehicles, complex electronic systems exist in close proximity to high-powered batteries and voltage systems where there is an increased potential for electronic data and performance interference. Providing shielding in increasingly effective and efficient forms remains an objective.

Accordingly, there is an ongoing desire to provide effective electronic shielding approaches. There is also a desire to provide shielding techniques tailored to the particular needs of electric vehicle equipment. Furthermore, other desirable features and characteristics of the present disclosure will become apparent from the subsequent detailed description and the appended claims, taken in conjunction with the accompanying drawings and the foregoing introduction.

### SUMMARY

In a number of embodiments, a method of shielding an electric component includes designing a shield to enclose, at least partly, the electric component. A shielding density of the shield is determined. Strands are produced from a combination of nonmetallic fibers and metallic wire. Fabric is woven from the strands with the metallic wire extending in at least two directions. The shield is formed from layers of the fabric combined with a resin.

In additional embodiments, no more than one metallic wire is included per strand. The one wire is disposed alongside the nonmetallic fibers.

In additional embodiments, the nonmetallic fibers and metallic wire are combined in a spooling machine, The metallic wires in the strands are made of two different metals.

In additional embodiments, the metallic wire is made of aluminum, copper and/or steel.

In additional embodiments, glass or carbon is used as the nonmetallic fibers.

In additional embodiments, the strands are woven in an interweaved plain weave pattern.

In additional embodiments, a series of layers of the fabric are stacked with interspersed non-shielding layers that do not include the metallic fibers.

In additional embodiments, the shield is formed as a battery enclosure for an electric vehicle.

In additional embodiments, the strands are interwoven so that the metallic wire forms a connected network where substantially all of the metallic wires are electrically coupled together.

In additional embodiments, the network is grounded to a vehicle.

In a number of other embodiments, a system of shielding an electric component includes a shield configured to enclose, at least partly, the electric component, where the shield has a predetermined shielding density. Strands are included in the shield and are a combination of nonmetallic fibers and metallic wire forming a woven fabric with the metallic wire extending in at least two directions. The shield is formed from layers of the woven fabric combined with a resin.

In additional embodiments, no more than one metallic wire is included per strand, where the one metallic wire is aligned alongside the nonmetallic fibers.

In additional embodiments, the nonmetallic fibers and the metallic wire are combined together in a spooling machine, where the metallic wires in the strands are comprised of two different metals.

In additional embodiments, the metallic wire is made of at least one of aluminum, copper and/or steel.

In additional embodiments, the nonmetallic fibers are made of at least one of glass and/or carbon.

In additional embodiments, the strands are woven in an interweaved plain weave pattern.

In additional embodiments, the shield includes a stack of a series of layers of the fabric with interspersed non-shielding layers that do not include the metallic material.

In additional embodiments, the shield is used as a battery enclosure for an electric vehicle.

In additional embodiments, the strands are interwoven so that the metallic wire forms a connected network where substantially all of the metallic wires in the strands are electrically coupled together, and the network is grounded to a vehicle.

In a number of other embodiments, a method of shielding an electric component of a vehicle includes designing a shield to enclose, at least partly, the electric component. Based on anti-interference requirements of the electric component and by testing, a shielding density of the shield is determined. Strands are produced of a combination material of nonmetallic fibers and metallic wire. Shielding fabric is woven from the strands of the combination material with the metallic wire extending in at least two directions. Reinforcement fabric is woven from the nonmetallic fibers without the metallic wire. The shield is formed from layers of the shielding fabric and layers of the reinforcement fabric, each combined with a resin. The shield is used to form a battery enclosure of the vehicle. The battery enclosure is grounded to the vehicle via a ground that connects the metallic wires with the vehicle.

### BRIEF DESCRIPTION OF THE DRAWINGS

The exemplary embodiments will hereinafter be described in conjunction with the following drawing figures, wherein like numerals denote like elements, and wherein:

FIG. 1 is a functional block diagram of a vehicle including a shielding system, in accordance with various embodiments;

FIG. 2 is schematic view of a section of a weaved reinforcement for the shielding system of FIG. 1, in accordance with various embodiments;

FIG. 3 is schematic, detail view of a section of a strand for the shielding system of FIG. 1, in accordance with various embodiments;

FIG. 4 is a schematic illustration of a feed system for strands of the reinforcement of FIG. 2, in accordance with various embodiments;

FIG. 5 is a schematic illustration of a built up shielding system, in accordance with various embodiments;

FIG. 6 is a schematic illustration of a molding operation of the shielding system of FIG. 1 in a preforming state, in accordance with various embodiments;

FIG. 7 is a schematic illustration of a molding operation of the shielding system of FIG. 1 in a forming state, in accordance with various embodiments;

FIG. 8 is a schematic illustration of a molding operation of the shielding enclosure for the shielding system of FIG. 1, in accordance with various embodiments; and

FIG. 9 is a flowchart of a process for a shielding system in relation to FIGS. 1-8, in accordance with various embodiments.

### DETAILED DESCRIPTION

The following detailed description is merely exemplary in nature and is not intended to limit the application and uses. Furthermore, there is no intention to be bound by any expressed or implied theory presented in the preceding introduction or the following detailed description.

In various embodiments, fiber reinforced composites are used as the shielding structures for shields, such as barriers and enclosures, of various modules in applications such as those of electrical vehicles. Shielding is provided to protect modules and other components from interference from outside sources and with each other. The solutions provided in the current disclosure are applicable in many applications including those where the geometry is complicated. Metal strands, such as of aluminum, copper or steel wire may be integrated and interwoven with structural strands such as of fiberglass or carbon fiber during the fiber weaving process. By using the pre-mixed fiber/metal wire materials, to weave the network of reinforcement, a faraday cage may be simultaneously built into the required geometry. After encasing the weave in cured resin via molding, the enclosure provides desirable shielding functions. The metal component in weave along with the reinforcement also enhances the toughness of the fiber/resin matrix.

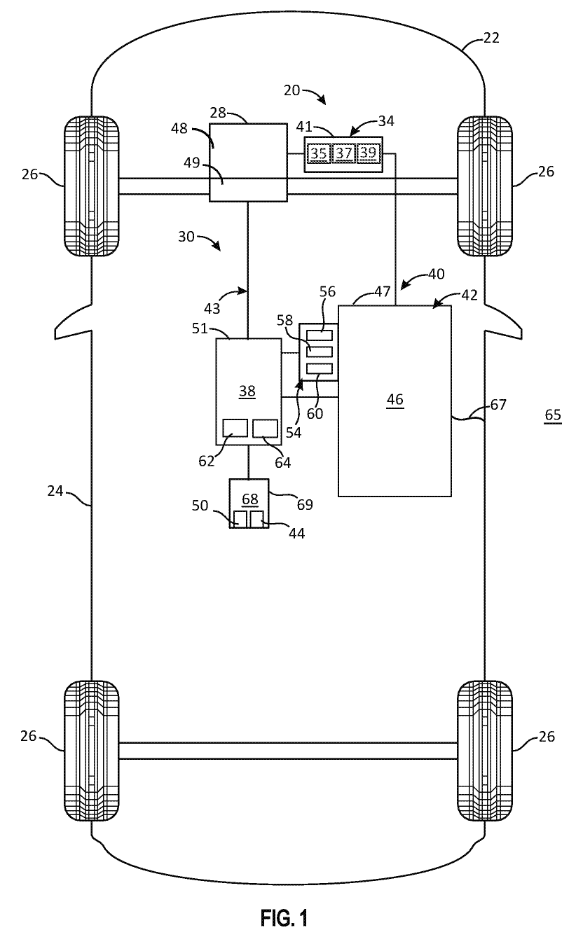

Referring to FIG. 1, an application within which an electromagnetic shielding enclosure for electronic modules, that is also referred to as a shielding system 20, may be employed is illustrated as a vehicle 22. While the shielding system 20 may be described within an embodiment of the vehicle 22, it is not limited to that embodiment but has application in a number of applications including in any environment avoiding EM RF and/or ED interference is desirable. As noted above, the shielding system 20 as described herein may be applied to various enclosures of any shape, size and format as well as to any electronic module or component.

As illustrated, the vehicle 22 includes a rechargeable energy storage system (RESS) 40 that includes the shielding system 20 according to an exemplary embodiment. The vehicle 22 includes shielding approaches that inhibit EM, RF and/or ED interference from affecting performance and reliability. In a number of embodiments, the vehicle 22 generally includes a body 24, four wheels 26, a powertrain 28, a control system 30, and the RESS 40. The body 24 substantially encloses the other components of the vehicle 22. The wheels 26 are each rotationally coupled to the body 24 near a respective corner. In some embodiments the control system 30 may be a plural number of integrated systems.

The vehicle 22 may be any one of a number of different types of automobiles, such as, for example, a sedan, a wagon, a truck, or a sport utility vehicle (SUV), and may be two-wheel drive (2WD) (i.e., rear-wheel drive or front-wheel drive), four-wheel drive (4WD) or all-wheel drive (AWD). The vehicle 22 may also incorporate any one of, or combination of, a number of different types of electrical propulsion systems, such as a combustion/electric motor hybrid engine and a battery electric vehicle.

In the exemplary embodiment, the vehicle 22 is an electric vehicle, and generally includes a controller 38, the above-referenced RESS 40, the control system 30, the powertrain 28, and power electronics 34. The powertrain 28 embodies an electric propulsion system that drives the wheels 26. More specifically, the powertrain includes an electric motor 48. As will be appreciated by one skilled in the art, the electric motor 48 is associated with a geartrain 49 or transmission as an integral or separate component. The power electronics 34 may include electric vehicle elements such as a power inverter module 35, an accessory power module 37 and an onboard charger module 39 in a power electronics enclosure 41.

The RESS 40 includes a battery module 42 in a battery enclosure 47 that is mounted on the body 24, and is electrically connected to the power electronics 34. In the current embodiment, the RESS 40 comprises at least one rechargeable battery pack having battery cells. In embodiments, the cells of the RESS 40 may be cylindrical, prismatic, pouch, or of another type. Together, the RESS 40 and the powertrain 28 comprise a drive system to propel the vehicle 22.

The controller 38 is contained in a controller enclosure 51. Generally, the controller 38 is configured to receive inputs from various sensors which are configured to generate signals in proportion to various physical input parameters associated with: the powertrain 28; the RESS 40; and their subsystems, and other interrelated systems. In the depicted embodiment, the controller 38 includes the processor 62 and a memory device 64, and is coupled with a storage device 68 that is contained in a data storage enclosure 69. During operation, the processor 62 executes one or more programs 44 and may use data 50, each of which may be contained within the storage device 68.

Within the context of the vehicle 22, the shielding system 20 may be employed in association with any number of locations, including at the power electronics enclosure 41, the battery enclosure 47, the controller enclosure 51, and/or the data storage enclosure 69. In embodiments, the shielding system may be applied to other devices and modules such as the powertrain 28 and its controller(s), the vehicle’s GPS unit, cables, buses, other modules and non-vehicular devices and modules. When applied, the shielding system 20 protects from the transmission of internal EM/RF to other devices, as well as from the entry of external EM/RF from other devices on board the vehicle 22 and from other offboard sources in the environment 65, such as from other vehicles, machines, transmission sources, etc. The shielding system 20 may also avoid ED interference and as such may be grounded to the vehicle 22 via a ground strap 67.

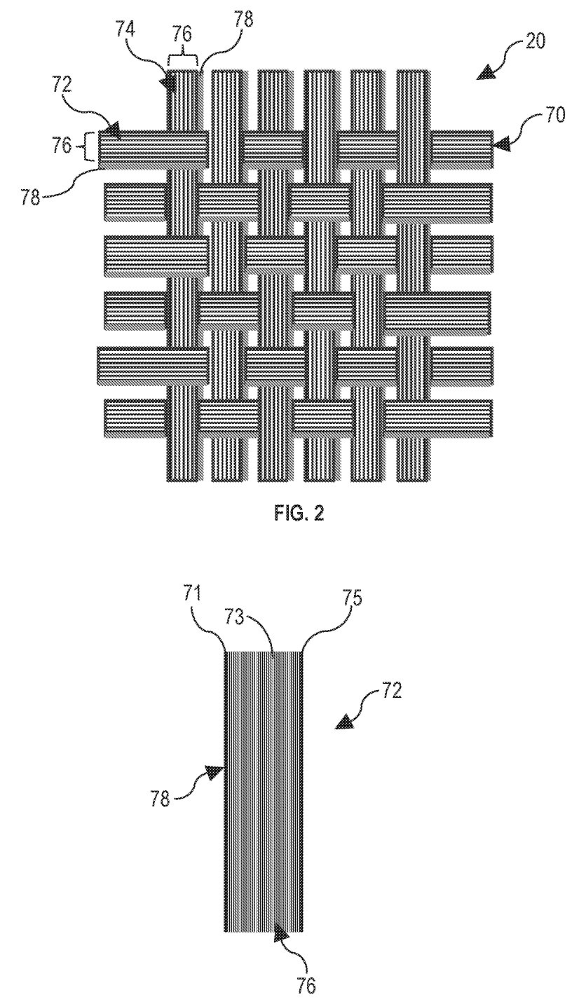

The shielding system 20 may be embodied in any of the mentioned enclosures or applications through the use of woven layers of material that may be incorporated into fabric sheets or structures for use in shielding. Referring to FIG. 2, one woven section 70 of fabric that includes interwoven materials in a bi-direction weft/warp type arrangement. As viewed in FIG. 2, a series of horizontal strands 72 are interwoven with a series of vertical strands 74. Each of the strands 72 and 74 includes a reinforcement section 76 and a shielding section 78. The reinforcement part may include bundled or otherwise oriented fibers such as those of glass, carbon or aramid. The reinforcement section 76 makes up a majority of each strand 72, 74. The shielding section 78 is a conductive thread/wire, or a plural number thereof, such as of aluminum, copper, steel, etc., or combinations or alloys thereof. The shielding section 78 is included in the stands 72 and 74 in both directions to minimize shielding gaps and to provide overlap and contact/interconnection points. As woven, each horizontal strand 72 passes over a vertical strand 74 and then under the next vertical strand 74. The same or another interweaving approach applies to the vertical strands 74 to create a plain weave or in embodiments a satin weave, 2x2 twill, non-crimp fabric, etc.. Each strand 72, 74 in the weave is a combination of the nonmetallic reinforcement section 76 and the metallic shielding section 78. Interweaving the strands 72, 74 is completed so that the metallic wire of the shielding sections 78 forms a contacted network where substantially all of the metallic wires in the woven strands 72, 74 are coupled together. The network is then grounded, such as via the ground strap 67 (FIG. 1). As a result, the use of metal is minimized while the woven section 70 has complete shielding coverage. When additional shielding is needed, multiple layers may be used and/or the number and diameter of the threads/wires of the shielding section 78 may be increased.

Referring to FIG. 3, a detail view of a strand 72, which may be used as the strands 72 and 74, shows a metallic wire 71 of the shielding section 78 disposed alongside the fibers 73 of the reinforcement section 76. In this example, a second metallic wire 75 is included as part of the shielding section 78. The metallic wire 75 is disposed on an opposite side of the fibers 73 from the metallic wire 71. In other embodiments, the metallic wires 71 and 75 may be disposed together on one side of the fibers 73 or may be disposed inside the middle of, or among, the fibers 73 of the reinforcement section 76. In embodiments, the metallic wires 71 and 75 may be the same metal e.g., aluminum, copper, steel, etc. In embodiments, the metallic wire 71 may be one metal, such as aluminum and the metallic wire 75 may be a different metal, such as copper.

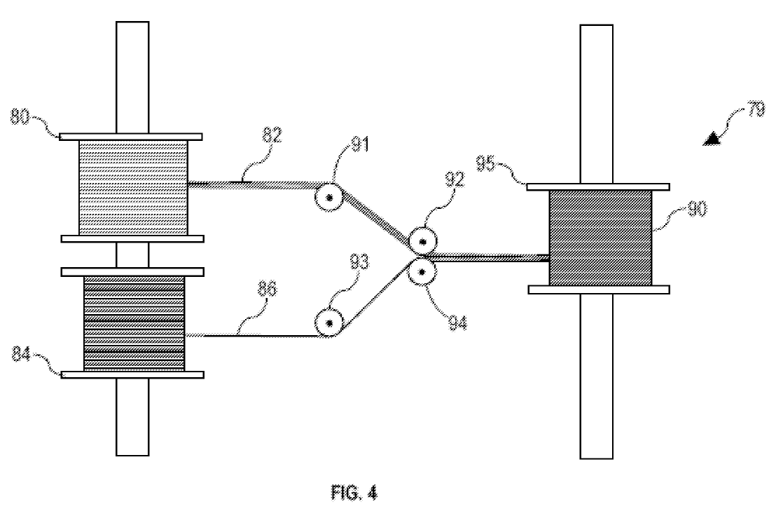

Referring to FIG. 4, the creation of the strands 72, 74 as the weaving material is shown using a spooling machine 79. A spool 80 of nonmetallic material 82 for the reinforcement section 76 and a spool 84 of metallic material 86 for the shielding section 78 are presented as feedstock. The feedstock is directed through various guides 91-94 of the spooling machine 79 that may be rollers, tubes, slotted blocks, etc., to direct the feedstock materials together in their desired orientation. In embodiments, the nonmetallic material 82 may be disposed alongside the metallic material 86 in the strands 72, 74. In other embodiments, the nonmetallic material 82 may be twisted with the metallic material 86. In other embodiments, the metallic material 86 may be interlaced with the nonmetallic material 82. In other embodiments. The two types of materials may be otherwise oriented to a desired relationship. In embodiments, the proportion of the metallic material 86 to the nonmetallic material 82 is defined based on the level of shielding required for the application. As properly combined and oriented, the weaving material 90 is wound on a spool 95 for use in weaving the fabric such as of the woven section 70 of FIG. 2.

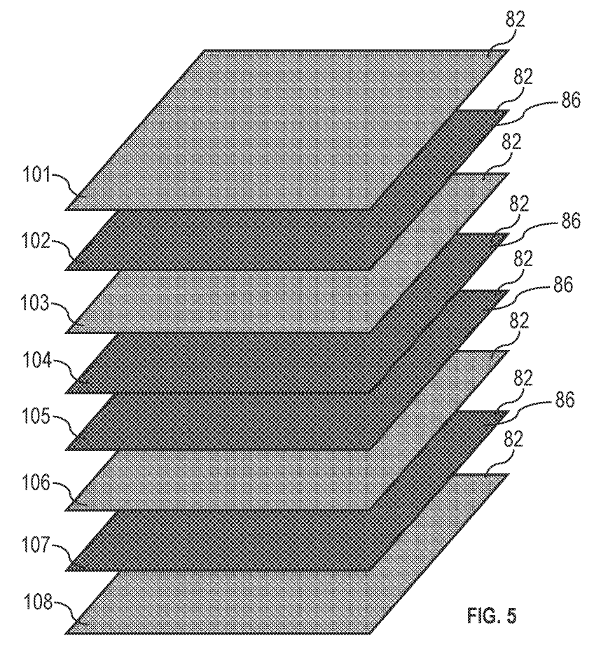

After weaving, the fabric may be combined in multiple layers such as illustrated in FIG. 5. As shown, eight layers 101-108 of fabric are combined, any of which may be shielding layers or reinforcement only layers. A shielding layer is one that includes both the metallic material 86 and the nonmetallic material 82. A reinforcement only layer is one that includes the nonmetallic material 86 but does not include the metallic material 86. In any given application, such as for the battery enclosure 47, the design requirements dictate the number of layers used to supply the required thickness, rigidity and other physical parameters of the product. As illustrated in FIG. 5, the layers 102, 104, 105 and 107 are shielding layers. The layers 101, 103, 106 and 108 are reinforcement only layers.

The number of shielding layers e.g., 102, 104, 105 and 107, included in an application is determined according to the design requirements. In one specific example, 50 decibels of attenuation may be required at the material level. Attenuation is an indicator of the effectiveness of shielding. Shielding is the difference between the intensity of electromagnetic signals passing through the material without shielding and the intensity after including the shielding. In this case, the attenuation is determined by comparing the product with all layers being the reinforcement only layers e.g., 101, 103, 106 and 108 as compared to inclusion of the shielding layers e.g., 102, 104, 105 and 107. Testing may be conducted to determine how many of the shielding layers e.g., 102, 104, 105 and 107 are needed for the required level of attenuation. Any number of shielding layers e.g., 102, 104, 105 and 107 may be included to provide the desired level of attenuation.

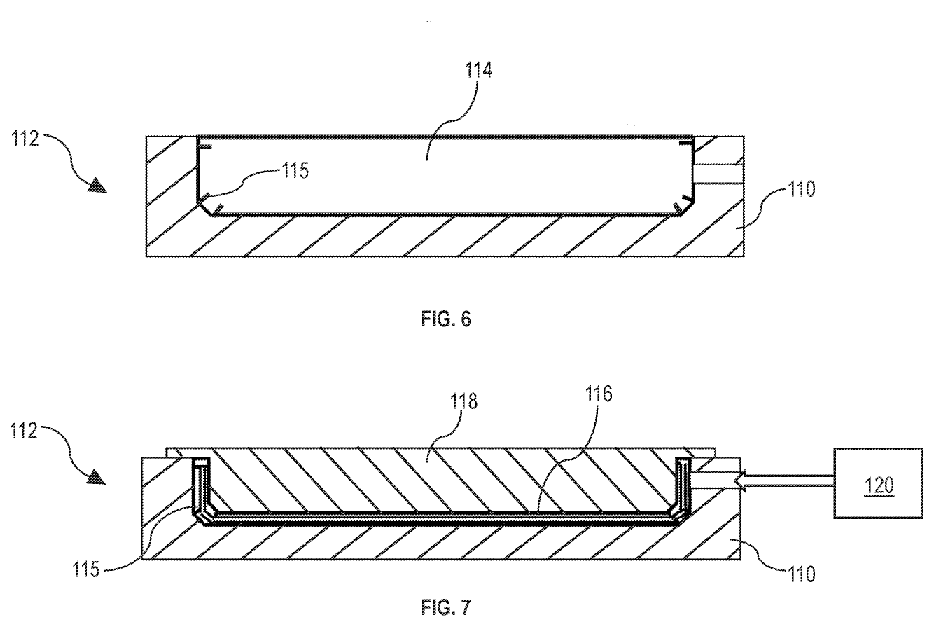

Referring to FIG. 6, the lower half 110 of a mold 112 is shown. The lower half 110 includes a cavity 114 within which a product, such as an enclosure, may be formed. The cavity 114 may be any desired shape for the product. Anchors 115 are included in the cavity to hold the reinforcement material in position during molding. An injection port extends through the lower half 110 into the cavity for the introduction of resin during molding. When resin infusion or RTM is employed, such as described in a resin infusion or RTM, a vacuum system or seal may be included for resin during molding. When using a prepreg approach, the prepreg layup may be pressed into the mold and cured without need of a resin port or anchors.

Referring to FIG. 7, the mold 112 is shown containing a collection 116 of laid up layers and with the upper half 118 of the mold 112 closed to the lower half 110. In embodiments, the collection 116 may be preformed to fit within the mold 112 or may be loose material that is laid into the mold 112 and held in place by the mating halves 110, 118 and the anchors 115. Resin may be introduced into the mold around the collection/preform 116 by an injector 120 forming at least a part of an enclosure.

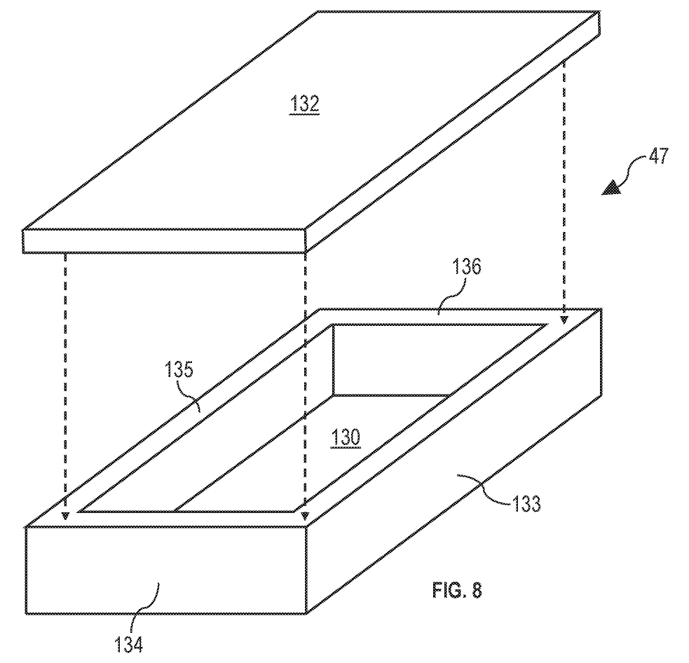

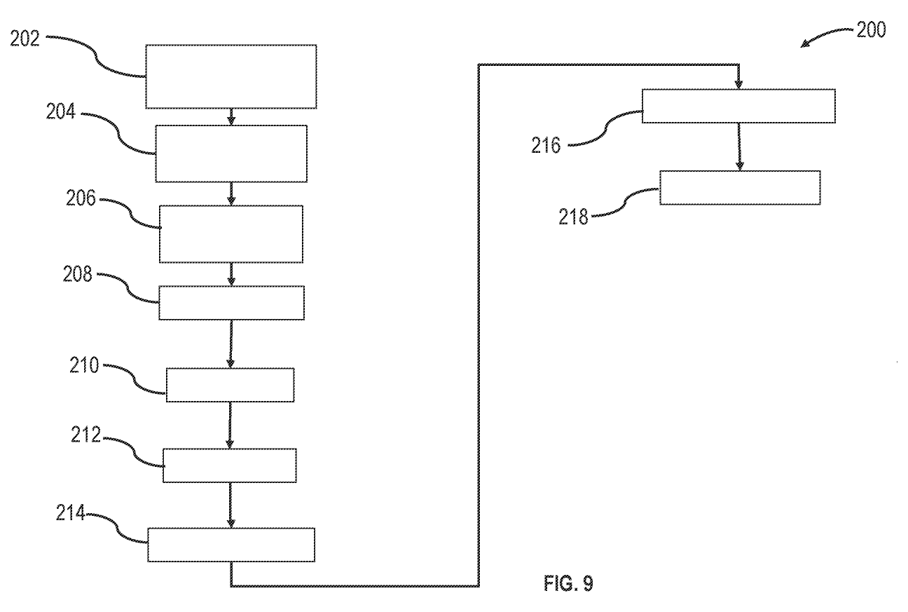

Referring to FIG. 8, an example enclosure is shown, embodied as the battery enclosure 47. The battery enclosure 47 includes a bottom 130, a top 132 and four sides 133-136, each of which includes the shielding layers e.g., 102, 104, 105 and 107 with the metallic material 86 and the nonmetallic material 86. In other embodiments, not all of the bottom 130, top 132 and four sides 133-136 include the shielding layers e.g., 102, 104, 105 and 107, when not needed by the applicable attenuation requirements. In other embodiments, the enclosure’s shape may take any form to match the device/ module of the application. In embodiments, the enclosure may be a shield of any shape and configuration, including complex shapes. In embodiments, composite components in a metallic tray, cover, or other form may be used.

As depicted in FIG. 9, a method 200 for electromagnetic shielding of electronic devices/ modules includes determining 202 attenuation requirements of a shielding product, such as of the battery enclosure 47. The shielding requirements may be determined 202 based on the EM/RF radiation generated by the components in the battery enclosure 47, generated by other components of the vehicle 22 and from exposure to radiation in the environment 65. Susceptibility of electronic components to interference may be determined by methods such as an open field testing, shielded box testing, shielded room testing, and/or transmission line testing. The attenuation needed may be expressed in decibels (dB). The attenuation requirements are determined based on the sensitivity of the electronic components to interference and may be expressed at a material, a component and/or a system level.

With the attenuation specification determined 202, the density of the metallic material 86 to the non-metallic material 82 is determined 204. This may include determining 204 the cross sectional size (e.g., diameter) of the metallic material, its composition e.g., aluminum, copper, steel, etc.), and the number of threads/wires included in each strand 72, 74. These parameters may be determined by testing, for example according to Standard D-4935 of the American Society for Testing and Materials: “Standard Test Method for Measuring the Electromagnetic Shielding Effectiveness of Planar Materials.” Testing may be conducted on variations of the materials to determine acceptable options. As an example, the arrangement of FIG. 2 includes one thread/wire of metallic material 86 in each strand 72, 74 along with many fibers of non-metallic material 82. The number of fibers of non-metallic material 82 in each strand 72, 74 may be the same or substantially the same as used for creating products without shielding to employ standard weaving and processing equipment.

With the density determined 204, the material for the strands 72, 74 may be prepared 206, such as using the spooling machine 79 of FIG. 4. The feedstock is prepared and combined to achieve the determined 204 density. The metallic material 86 may be selected for a number of conductive metals such as aluminum, copper, steel, alloys thereof, plated or coated versions thereof, etc. For example, the wire surface may be treated via chromate conversion for protection and added adhesion to the resin. The non-metallic material 82 may be selected to provide the mechanical properties needed from the finished product and as suitable for the employed molding process. Examples include glass, carbon, aramid, etc. The metallic material 86 may be extruded wire produced with a deformed surface or mildly acid etched to cause non-uniformity to the surface, to promote bonding between the wire and resin during molding.

The material of the strands 72, 74 are then used to weave 208 fabric. The pattern of the weave may vary with the strands 72, 74 extending in at least two directions and crossing each other to provide coverage of the fabric with the metallic material 86 with minimal gaps between adjacent threads/wires. The selected weave pattern may also be identified as a result of testing, such as using the method described above.

The woven 208 fabric may be cut to size and stacked/layered 210 according to design specifications to achieve the required thickness and strength of the product and to provide the determined 202 level of attenuation. The number of shielding layers e.g., 102, 104, 105 and 107 with the shielding metallic material 86 and the number that are reinforcement only layers e.g., 101, 103, 106 and 108, are stacked. The stacked layers may be laid up for creating the product. In embodiments, the stacked 210 layers may be prepregs or preformed.

The stacked 210 layers may be laid 212 in the mold 112, such as shown in FIG. 6. Laying up may be done using a robot. A molding process such as resin transfer molding may be employed. The mold 112 is closed and the resin is injected to saturate the layers and form the product. In embodiments, the manufacturing process employed may be open tool molding (autoclave), liquid compression molding, resin transfer molding, compression molding, injection molding, pultrusion, etc.. In an example, processing may include weaving of strands, preparing a prepreg with resin, layup for prepreg processing, and molding.

Following setup, the product, such as the battery enclosure 47, is formed/molded 214 or a part thereof, is removed 216 from the mold 112. The product is then assembled 218 in the vehicle 22 for use and to provide shielding. Grounding of the metallic material 86 to the vehicle 22 may be located to coincide with existing to fastener locations, or any other convenient locations. Desirable levels of shielding tailored to each electronic device are achieved without interfering with the mechanical properties of the otherwise employed composite/plastic material.

Accordingly, fiber reinforced composites are provided for shielding in applications such as the enclosures of a battery pack and various modules in electrical vehicles. Electromagnetic shielding is provided to protect the modules from interference, including with each other. Approaches are provided that avoid challenges associated with using foil for shielding at locations where the geometry is complicated, or difficult to manage in molding. Metal threads/wire is included during the fiber weaving process. By using combined fiber/wire strands to weave the network of reinforcement, a Faraday cage is simultaneously built into the required geometry. After encasing the weave in cured resin via molding, the enclosure provides the electromagnetic shielding function. The threads/wire also enhances the toughness of the resin matrix.

Depending on the thickness of the enclosure or product, the woven sheets with reinforcement fibers and wire may be arranged is alternate layers or other arrangements to tailor the manufacturing process to meet the design requirement. Selective layering enhances the effect of the electromagnetic shielding while providing efficiency and limiting weight. The orientation of each layer can rotate to different angles to enhance or minimize the anisotropic behavior of the composite.

The addition of metal threads/wires in the weaving process may be used to improve the toughness of the resin composite. Due to the high modulus of metal wires, the thickness of the enclosure may be reduced. Further, due to the higher thermal conductivity of metal wires, the addition of metal wires assists thermal dissipation of the heat generated by the electronics inside the enclosure.

Weaving the mixture of fiber and wires, laying up and other steps may be robotic or otherwise automated for efficiency and effectiveness.

While at least one exemplary embodiment has been presented in the foregoing detailed description, it should be appreciated that a vast number of variations exist, including variation in resin introduction or manufacturing methodology. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A method of shielding an electric component comprising:
designing a shield to enclose, at least partly, the electric component;
determining a shielding density of the shield;
producing strands from a combination of nonmetallic fibers and metallic wire;
weaving fabric from the strands with the metallic wire extending in at least two directions; and
forming the shield from layers of the fabric combined with a resin.

2. The method of claim 1, comprising:
including no more than one metallic wire per strand; and
aligning the one wire alongside the nonmetallic fibers.

3. The method of claim 1, comprising:
combining the nonmetallic fibers and metallic wire in a spooling machine; and
including metallic wires in the strands of two different metals.

4. The method of claim 1, comprising selecting at least one of aluminum, copper and steel as the metallic wire.

5. The method of claim 1, comprising selecting glass, aramid or carbon as the nonmetallic fibers.

6. The method of claim 1, comprising weaving the strands in an interweaved pattern.

7. The method of claim 1, comprising stacking a series of layers of the fabric with interspersed non-shielding layers that do not include the metallic fibers.

8. The method of claim 1, comprising forming the shield as a battery system component for an electric vehicle.

9. The method of claim 1, comprising interweaving the strands so that the metallic wire forms a connected network where substantially all of the metallic wires are electrically coupled together.

10. The method of claim 9, comprising grounding the network to a vehicle.

11. A system of shielding an electric component comprising:
a shield configured to enclose, at least partly, the electric component, wherein the shield has a predetermined shielding density; and
strands in the shield comprising a combination of nonmetallic fibers and metallic wire forming a woven fabric with the metallic wire extending in at least two directions,
wherein the shield is formed from layers of the woven fabric combined with a resin.

12. The system of claim 11, wherein no more than one metallic wire is included per strand, wherein the one metallic wire is aligned alongside the nonmetallic fibers.

13. The system of claim 11, wherein the nonmetallic fibers and the metallic wire are configured to be combined in a spooling machine, wherein metallic wires in the strands are comprised of two different metals.

14. The system of claim 11, wherein the metallic wire comprises at least one of aluminum, copper and steel.

15. The system of claim 11, wherein the nonmetallic fibers comprise at least one of glass, aramid or carbon.

16. The system of claim 11, wherein the strands are woven in an interweaved pattern.

17. The system of claim 11, wherein the shield includes a stack of a series of layers of the fabric with interspersed non-shielding layers that do not include the metallic material or with all shielding layers.

18. The system of claim 11, wherein the shield comprises a battery system component for an electric vehicle.

19. The system of claim 11, wherein the strands are interwoven so that the metallic wire forms a connected network where substantially all of the metallic wires in the strands are electrically coupled together, wherein the network is grounded to a vehicle.

20. A method of shielding an electric component of a vehicle comprising:
designing a shield to enclose, at least partly, the electric component;
determining, based on anti-interference requirements of the electric component and by testing, a shielding density of the shield;
producing strands of a combination material that is a combination of nonmetallic fibers and metallic wire;
weaving shielding fabric from the strands of the combination material with the metallic wire extending in at least two directions;
weaving reinforcement fabric from the nonmetallic fibers without the metallic wire; and
forming the shield from layers of the shielding fabric and layers of the reinforcement fabric, each combined with a resin,
wherein the shield comprises a battery enclosure of the vehicle,
wherein the battery enclosure is grounded to the vehicle via a ground that connects the metallic wires with the vehicle.
